(19) United States
(12) Patent Application Publication
(10) Pub. No.: US 2006/0165147 A1
(43) Pub. Date: Jul. 27, 2006

(54) Single mode distributed feedback laser

(75) Inventor: In Kim, Suwon-si (KR)

Correspondence Address: CHA & REITER, LLC, 210 ROUTE 4 EAST STE 103, PARAMUS, NJ, 07652, US

(73) Assignee: Samsung Electronics Co., LTD.

(21) Appl. No.: 11/199,479

(22) Filed: Aug. 8, 2005

(30) Foreign Application Priority Data
Jan. 21, 2005 (KR) 2005-5990

(51) Int. Cl. H01S 3/08; H01S 5/00

(52) U.S. Cl. 372/96; 372/45.01; 372/50.11

(57) ABSTRACT

A single mode distributed feedback laser for producing a single mode light comprises a semiconductor substrate; a lower clad positioned on the semiconductor substrate and having a plurality of gratings that are arranged to be spaced apart at regular periods from one another; a waveguide grown on the lower clad to oscillate the light, the waveguide being formed to be curved in a direction perpendicular to a direction in which the gratings are arranged; an upper clad grown on the waveguide; and upper and lower electrodes.

### CLAIM OF PRIORITY

This application claims priority to an application entitled “Single mode distributed feedback laser,” filed in the Korean Intellectual Property Office on Jan. 21, 2005 and assigned Serial No. 2005-5990, the contents of which are hereby incorporated by reference.

### BACKGROUND OF THE INVENTION

1. Field of the Invention

The present invention relates to a single mode distributed feedback laser and more particularly, to a distributed feedback laser having gratings.

2. Description of the Related Art

A distributed feedback laser is widely used in optical communication as a source for producing single mode light and comprises Bragg gratings formed on a waveguide.

FIG. 1 illustrates a conventional distributed feedback laser. As shown, the conventional distributed feedback laser 100 comprises a semiconductor substrate 110, a lower clad 120 formed with gratings 121, a waveguide 130 grown on the lower clad 120, an upper clad 140 grown on the waveguide 130, lower and upper electrodes 151 and 152, and non-reflective and highly reflective layers 161 and 162.

The waveguide 130 is comprised of a lower waveguide 131, a multi-quantum well 132 and an upper waveguide 133 which are sequentially grown on the lower clad 120. By way of the gratings 121, the waveguide 130 produces light having a pair of peaks which are bilaterally symmetrized while being centered on a Bragg wavelength. Of the peaks constituting the light, the peaks whose electric filed distribution matches to the grating phase between the non-reflective layer 161 and the highly reflective layer 162 are oscillated as laser light. Since the non-reflective layer 161 can transmit a higher output than the highly reflective layer 162, the laser light oscillated from the distributed feedback laser 100 is outputted through the non-reflective layer 161.

In order to produce laser light having a wavelength range of 800˜1,600 nm, in the distributed feedback laser 100, the gratings 121 having a period of 100˜250 nm are formed in the lower clad made of an InP or GaAs-based semiconductor material. In the distributed feedback laser 100, electric field distribution varies depending on the length variations between the non-reflective and highly reflective layers 161 and 162 as well as the phase relationship of the gratings. A variation in the electric field distribution changes the single mode characteristic of the oscillated laser light. In the distributed feedback laser 100, the single mode characteristic of the oscillated laser light is based on a statistical phase distribution between the gratings 121 and the non-reflective and highly reflective layers 161 and 162, which is uncontrollable while implementing the process. Therefore, in the conventional distributed feedback laser 100, a yield in respect of a single mode characteristic remarkably decreases.

The Bragg wavelength of the distributed feedback laser 100 is determined depending upon a relationship between a period of the gratings 121 and an effective refraction index of the waveguide 130. As a method for improving a single mode characteristic of the distributed feedback laser 100, a stripe engineered structure in which the mesa width of the waveguide 130 is changed, and a chirped grating structure which comprises a plurality of gratings having different periods have been disclosed in the art.

In the chirped grating structure, there are formed a plurality of gratings having different periods. A distributed feedback laser which is formed with the chirped grating structure is disclosed in G. P. Agrawal and A. H. Bonbeck, “Modeling of Distributed Feedback Semiconductor Laser with Axially-Varying Parameters”, IEEE Journal of Quantum Electronics, vol. 24, No. 12, pp. 2407˜2414, December, 1988 [Reference 1].

A distributed feedback laser having the chirped grating structure typically employs an electron beam lithography instead of the conventional hologram lithography. However, the electron beam lithography for forming the chirped grating structure has drawbacks in that processes are complex, and a manufacturing cost is high. Further, it is not easy to precisely control an interval between the gratings at a desired level

In the conventional semiconductor laser, in order to obtain a lateral single mode, a method of forming a waveguide having a ridge or buried hetero structure has been used. In the above-described structure, a method for changing an effective refraction index (n_{eff}) by changing a stripe width of the waveguide is known as a stripe engineered grating method. This method has been proposed for replacing the distributed feedback laser having a chirped grating structure, which is manufactured by the electron beam lithography.

The following Equation 1 illustrates a relationship among Bragg wavelength, effective refraction index and period of gratings.
λ_{B}=2n_{eff}Λ [Equation 1]

In Equation 1, λ_{B} designates a Bragg wavelength of a grating, Λ a period of a grating, and n_{eff} an effective refraction index. Referring to FIG. 2, it is to be readily understood that a mesa width and an effective refraction index are proportional to each other.

In the above-described stripe engineered grating structure, a width of a waveguide changes depending upon a light traveling direction. A stripe engineered grating structure is disclosed in F. Grillot, B. Thedrez, F. Mallecot, C. Chaumont, S. Hubert, M. F. Martineau, A. Pinquier, and L. Roux, “Analysis, Fabrication, and Characterization of 1.55-μm Selection-Free Tapered Stripe DFB Lasers”, IEEE Photonics Technology Letters, vol. 14, No. 8, pp. 1040˜1042, August 2002 [Reference 2], and F. Grillot, B. Thedrez, F. Mallecot and G H. Duan, “Feedback Sensitivity and Coherence Collapse Threshold of Semiconductor DFB Lasers with Complex Structures”, IEEE Journal of Quantum Electronics, vol. 40, No. 3, pp. 231˜240, March 2004 [Reference 3].

FIG. 3 illustrates a kink phenomenon which occurs in the distributed feedback laser having the stripe engineered grating structure. As shown, in the distributed feedback laser having the stripe engineered grating structure which possesses a tapered configuration in which a mesa width changes at a specified position on the waveguide, a problem is caused in that, even though a constant voltage is actually applied, a kink phenomenon occurs, in which a semiconductor laser has an operational characteristic in which an applied current distribution abruptly changes near a threshold current.

The kink phenomenon occurs because a current difference is induced depending upon a width of a waveguide in the case of differentiating a line width of a waveguide and thereby current flow abruptly changes before and after laser oscillation.

### SUMMARY OF THE INVENTION

Accordingly, the present invention has been made to solve the above-mentioned problems occurring in the prior art and provides additional advantages, by provising a distributed feedback laser which can be easily manufactured and has an improved single mode behavior.

In one embodiment, there is provided a single mode distributed feedback laser for producing single mode light which includes a semiconductor substrate; a lower clad positioned on the semiconductor substrate and having a plurality of gratings which are arranged to be spaced apart at regular periods from one another; a waveguide grown on the lower clad to oscillate the light, the waveguide being formed to be curved in a direction perpendicular to a direction in which the gratings are arranged; an upper clad grown on the waveguide; an upper electrode formed on the upper clad; and a lower electrode formed on a lower surface of the semiconductor substrate.

### BRIEF DESCRIPTION OF THE DRAWINGS

The above features and advantages of the present invention will be more apparent from the following detailed description taken in conjunction with the accompanying drawings, in which:

FIG. 1 is a view illustrating a conventional distributed feedback laser;

FIG. 2 is a graph illustrating a relationship between a mesa width and an effective refraction index;

FIG. 3 is a graph explaining a kink of an output depending upon a current generated in a conventional distributed feedback laser having a stripe engineered structure;

FIG. 4 is a drawing illustrating a distributed feedback laser in accordance with an embodiment of the present invention;

FIG. 5 is a sectional view illustrating a waveguide of the distributed feedback laser shown in FIG. 4;

FIG. 6 is a graph explaining a relationship between tilt degrees and wavelengths of oscillation modes;

FIG. 7 is a graph explaining a Bragg wavelength and a coupling coefficient along the laser length;

FIG. 8 is a view illustrating gratings and a waveguide structure according to a variation of the present invention; and

FIG. 9 is a view illustrating gratings and a waveguide structure according to another variation of the present invention.

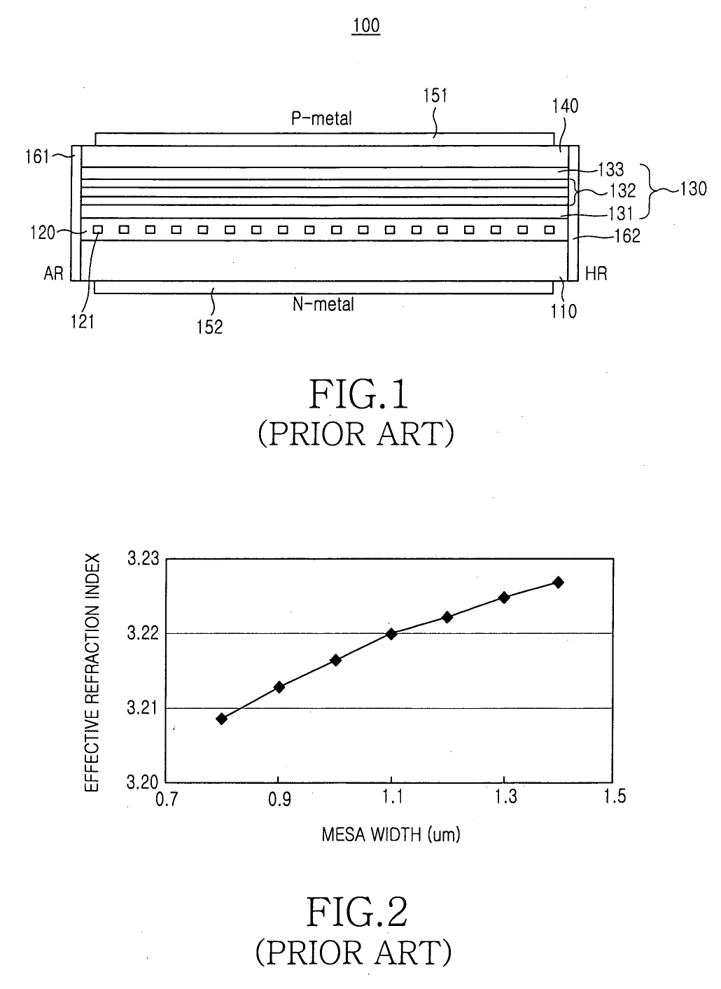

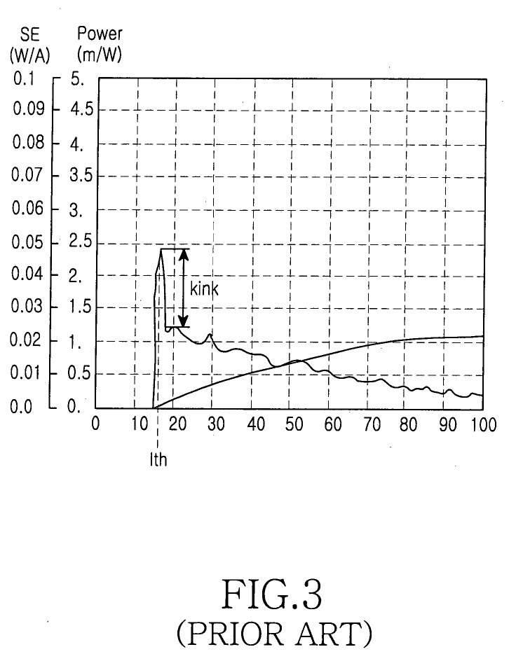

### DETAILED DESCRIPTION

Hereinafter, embodiments of the present invention will be described with reference to the accompanying drawings. In the following description, the same elements will be designated by the same reference numerals although they are shown in different drawings. Further, various specific definitions found in the following description, such as specific values of packet identifications, contents of displayed information, etc., are provided only to help general understanding of the present invention, and it is apparent to those skilled in the art that the present invention can be implemented without such definitions. Further, for the purposes of clarity and simplicity, a detailed description of known functions and configurations incorporated herein will be omitted as it may make the subject matter of the present invention unclear.

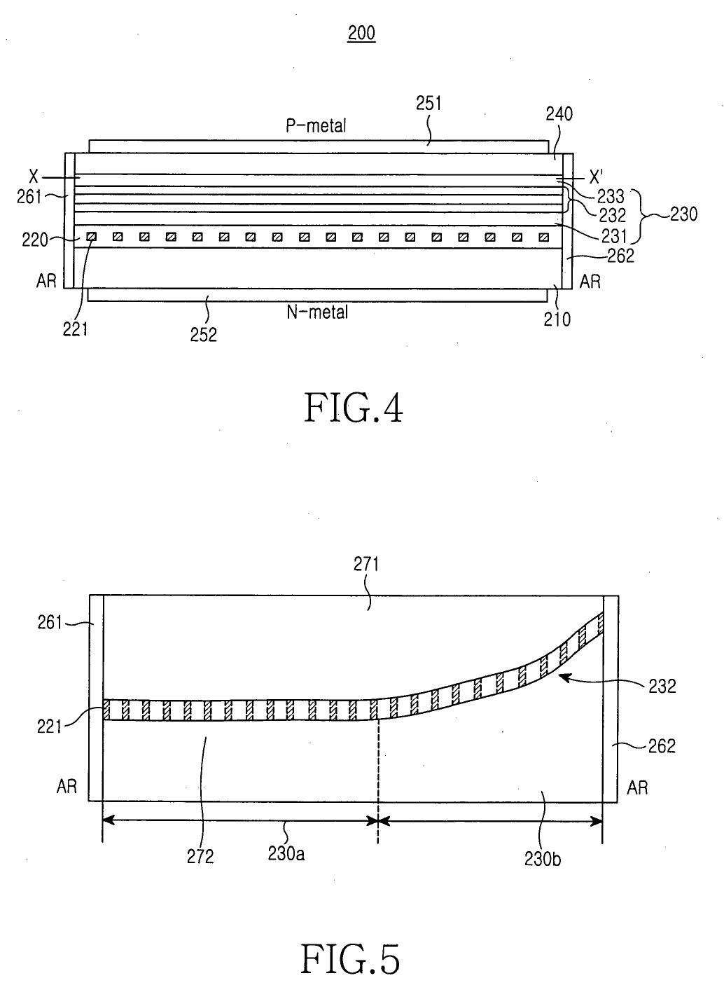

FIG. 4 is a drawing illustrating a distributed feedback laser in accordance with an embodiment of the present invention. As shown, a distributed feedback laser 200 includes a semiconductor substrate 210, a lower clad 220 grown on the semiconductor substrate 210 and having a plurality of gratings 221 arranged in art at constant interval, a waveguide 230 grown on the lower clad 220 formed to be curved in a direction perpendicular to a direction in which the gratings 221 are arranged for oscillating the light, an upper clad 240 grown on the waveguide 230, upper and lower electrodes 251 and 252 formed to apply current to the distributed feedback laser 200, and non-reflective layers 261 and 262.

The lower clad 220 is grown on the semiconductor laser 210, and the plurality of gratings 221 are formed in the lower clad 220 so that they are spaced apart from one another at constant periods Λ. The waveguide 230 includes a lower waveguide 231, a multi-quantum well 232, and an upper waveguide 232 which are sequentially deposited on the lower clad 220.

FIG. 5 is a sectional view illustrating the waveguide 230 of the distributed feedback laser shown in FIG. 4. As shown, the waveguide 230 has a first area 230a formed in the shape of a straight line in a direction in which the gratings 221 are arranged, and a second area 230b extending from the first area 230a and curved at a predetermined angle in a direction perpendicular to the direction in which the gratings 221 are arranged.

The waveguide 230 is grown to have a predetermined height when measured from the lower clad 220. After this growth process, the second area 230b which extends from the first area 230a can be formed through mesa etching or ridge etching.

Due to the fact that the second area 230b of the waveguide 230 is formed to be curved at the predetermined angle in the direction perpendicular to the direction in which the gratings 221 are arranged, while a physical periodic interval Λ of the gratings 221 is constant, an effective grating period of the gratings 221 which are positioned below the second area 230b changes depending upon a curved angle θ of the second area 230b. That is to say, the gratings 221 can be formed without employing an electron beam lithography which is generally used for forming a chirped grating structure.

The corresponding gratings 221 which are formed in the second area 230b have the same operational characteristic as an effective period is lengthened, a Bragg wavelength of the light produced in the second area 230b approaches a long wavelength.

$${λ}_{B} = \frac{2 {n}_{eff} Λ}{cos θ} = 2 {n}_{eff} ( 1 + \frac{{θ}^{2}}{2} ) \qquad [ Equation 2 ]$$

In Equation 2, λ_{B} represents a Bragg wavelength, n_{eff} represents an effective refraction index of the waveguide 230, θ represents an angle at which the second area 230b is curved in the direction perpendicular to the direction in which the gratings 221 are arranged, and Λ represents a period of the gratings 221.

The waveguide 230 produces light having a pair of peaks which are bilaterally symmetrized while being centered on a Bragg wavelength, the peaks whose electric filed distribution matches to the grating phase between the non-reflective layer 161 and the highly reflective layer 162 are oscillated as laser light. As described above, the characteristic of the distributed feedback laser 200, which oscillates laser light having a single wavelength, is known as a single mode characteristic.

Referring to Equation 2, it is to be readily appreciated that the Bragg wavelength of the light can be determined depending upon a period of the gratings 221, an effective refraction index of the waveguide 230, and an angle θ at which the second area 230b is curved in the direction perpendicular to the direction in which the gratings 221 are arranged.

The first area 230a can produce first light having a first Bragg wavelength, and the second area 230b can produce second light having a second Bragg wavelength which is spaced apart from the first Bragg wavelength by a predetermined wavelength. Each of the first and second light comprises a pair of peaks which are bilaterally symmetrized while being centered on the corresponding Bragg wavelength. In the distributed feedback laser 200 according to the present invention, by overlapping the peaks of the first and second light which has the same wavelength as the center wavelength of the laser light to be oscillated, it is possible to oscillate laser light having an improved single mode characteristic. In other words, by adjusting the slope θ of the second area 230b, specific peaks of the first and second light can be overlapped with the center wavelength of the laser light to be oscillated.

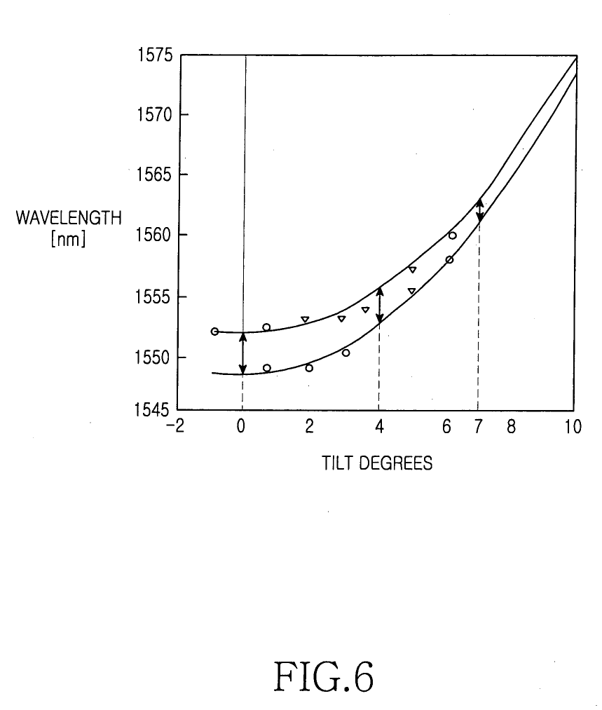

FIG. 6 is a graph illustrating a relationship between a tilt degree of the waveguide and a wavelength. As shown, when observing the cases in which the angle θ of the second area is respectively 0°, 4° and 7°, Bragg reflection effect accomplished in the vicinity of 4° remarkably reveals a peak characteristic which approaches the long wavelength than the case of 0°, whereby a chirped characteristic is achieved. On the contrary, in the case of 7°, as a coupling coefficient becomes small, an operational characteristic such as a chirped characteristic cannot be achieved.

For instance, it is preferred that the second area 230b have a length of 70˜100 μm and an angle curved within the range of 5˜10 μm be 0°˜7°. More preferably, the curved degree θ of the second area 230b continuously changes within the range of 0°˜7° to be unsusceptible to a small variation between designed and actually manufactured devices.

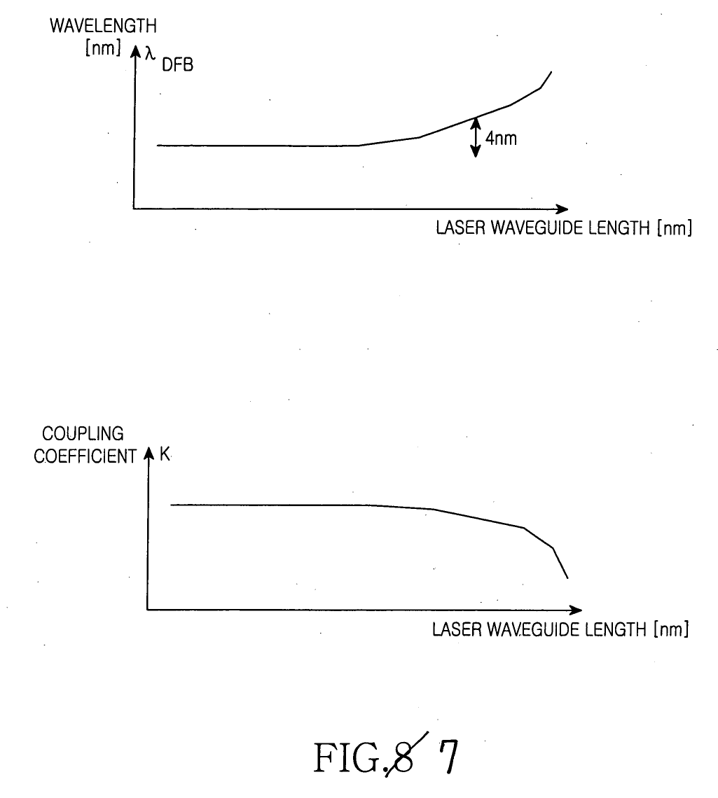

FIG. 7 is a graph showing a Bragg wavelength and a coupling coefficient in a lengthwise direction of the distributed feedback laser. As shown, by applying gratings which have a high coupling coefficient possessing a stop band of about 4 nm at 0°, to the distributed feedback laser 200 according to the present invention, it is possible to accomplish an operational characteristic of the chirped gratings.

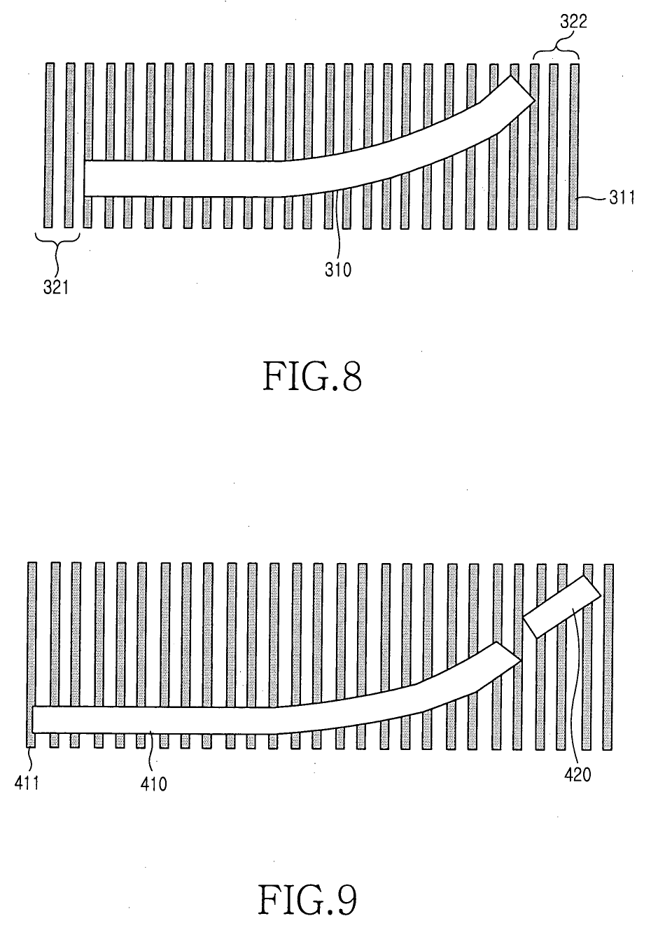

FIG. 8 is a view illustrating gratings and a waveguide structure according to a variation of the present invention. Gratings 311 adopted in FIG. 8 include window areas 321 and 322 at both ends of a waveguide 310. The window areas 321 and 322 of the gratings 311 can be formed in a mesa etching procedure of the waveguide 310.

The window area 321 and 322 can perform the function of preventing light from being inputted to the inside of the distributed feedback laser through non-reflective layers (not shown). It is preferred that the window areas 321 and 322 have a length of about 20 μm.

FIG. 9 is a view illustrating gratings and a waveguide structure according to another variation of the present invention. As shown, a waveguide 410 shown in FIG. 9 is formed in an etching procedure to be spaced apart from a monitoring photodiode (MPD) 420 by a predetermined interval. Gratings 411 are further formed on the waveguide 410 and the monitoring photodiode 420. The monitoring photodiode 420 can be formed through electrical insulation in an Fe-added InP re-growth procedure at a position separated from the waveguide 410 by about 30 μm.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A single mode distributed feedback laser for producing single mode light, comprising:
a semiconductor substrate;
a lower clad, provided on the semiconductor substrate, having a plurality of gratings arranged apart at regular periods from one another;
a waveguide grown on the lower clad to oscillate the light, the waveguide being formed to be curved in a direction perpendicular to a direction in which the gratings are arranged; and
an upper clad grown on the waveguide.

2. The single mode distributed feedback laser according to claim 1, further comprising:
non-reflective layers deposited on a first surface from which the light is outputted and on a second surface which is opposite to the first surface.

3. The single mode distributed feedback laser according to claim 1, wherein the waveguide includes a lower waveguide, a multi-quantum well and an upper waveguide which are sequentially deposited on the lower clad.

4. The single mode distributed feedback laser according to claim 1, wherein the waveguide is etched to have a mesa structure.

5. The single mode distributed feedback laser according to claim 1, further comprising:
a current blocking layer grown on a mesa side wall to adjoin the waveguide.

6. The single mode distributed feedback laser according to claim 1, wherein the waveguide has a first area formed in the shape of a straight line in a direction in which the gratings are arranged, and a second area extending from the first area and curved at a predetermined angle in a direction perpendicular to the direction in which the gratings are arranged.

7. The single mode distributed feedback laser according to claim 6, wherein the first area has a length of 200˜300 μm.

8. The single mode distributed feedback laser according to claim 6, wherein the second area extends from the first area by a length of 70˜100 μm in a direction in which the light travels.

9. The single mode distributed feedback laser according to claim 6, wherein the second area is curved within a length of 5˜10 μm in a direction perpendicular to the direction in which the light travels.

10. The single mode distributed feedback laser according to claim 1, further comprising:
a lower electrode formed on a lower surface of the semiconductor substrate; and
an upper electrode formed on the upper clad.

11. A method for providing a single mode distributed feedback laser used to generate a single mode light, the method comprising the steps of:
providing a semiconductor substrate;
providing a lower clad on top of the semiconductor substrate with a plurality of gratings, in sequence, arranged apart at a predetermined interval from one another;
providing a waveguide on the lower clad and having a curved shape i a direction perpendicular to a direction in which the gratings are arranged; and
providing an upper clad on the waveguide.

12. The method of claim 11, further comprising the step of: providing non-reflective layers deposited on a first surface from which the light is outputted and on a second surface which is opposite to the first surface.

13. The method of claim 11, wherein the waveguide is etched to have a mesa structure.

14. The method of claim 11, further comprising the step of: providing a current blocking layer on a mesa sidewall to adjoin the waveguide.

15. The method of claim 11, wherein the waveguide comprises a first area formed in the shape of a straight line in a direction in which the gratings are arranged, and a second area extending from the first area and curved at a predetermined angle in a direction perpendicular to the direction in which the gratings are arranged.

16. The method of claim 11, further comprising the step of: forming a lower electrode on a lower surface of the semiconductor substrate; and forming an upper electrode on the upper clad.
